(19) United States
(12) Patent Application Publication
(10) Pub. No.: US 2025/0167064 A1
(43) Pub. Date: May 22, 2025

(54) SYSTEM AND METHODS FOR ON-CHIP HEAT ROUTING ARCHITECTURES

(71) Applicant: Samsung Electronics Co., Ltd., Suwon-si (KR)

(72) Inventors: Radwanul Hasan SIDDIQUE, Monrovia, CA (US); Yibing Michelle WANG, Pasadena, CA (US); Haeri Park HANANIA, Sierra Madre, CA (US); Shailabh KUMAR, Pasadena, CA (US)

(21) Appl. No.: 18/893,952

(22) Filed: Sep. 23, 2024

Related U.S. Application Data
(60) Provisional application No. 63/602,366, filed on Nov. 22, 2023.

(51) Int. Cl. H01L 23/367; H01L 21/48; H01L 23/373; H01L 23/48

(52) U.S. Cl. CPC H01L 23/367; H01L 21/4882; H01L 23/3738; H01L 23/481

(57) ABSTRACT

Methods, systems and devices are disclosed including a substrate, a computational device mounted on the substrate, with a first surface of the substrate having one or more nanoelements formed within, the one or more nanoelements having a diameter of 100 nm-5,000 nm. In some embodiments, a heat dissipator may be mounted on the substrate, the heat dissipator having at least one nanostructure, and the one or more nanoelements forming a thermal conductive pathway between the computational device and the heat dissipator.

### CROSS-REFERENCE TO RELATED APPLICATION

This application claims the priority benefit under 35 U.S.C. § 119(e) of U.S. Provisional Application No. 63/602,366 filed on Nov. 22, 2023, the disclosure of which is incorporated herein by reference in its entirety.

### TECHNICAL FIELD

The subject matter disclosed herein relates to microelectronics packaging and integrated circuits (IC) packaging. More particularly, the subject matter disclosed herein relates to a package architecture involving the nanomaterials and nanostructures.

### BACKGROUND

Semiconductor devices may connect to additional devices and circuitry on different substrates. Forming connections between substrates can provide increased computation. However, forming connections between substrates can cause difficulties. Packaging describes the general method for connecting and integrating multiple computational components together in an integrated unit, and may involve multiple different types of integrated circuits on multiple substrates which may combine into a single unit. Packaging may also describe a method for which multiple computational components within a single unit are protected by the use of various techniques to provide thermal, physical and electrical protection It is further noted that background concepts discussed herein are for informational purposes only and are not intended to limit the present disclosure. Nor should the background or field described herein be intended to limit the disclosure herein to a particular use or concept.

### SUMMARY

An example embodiment provides a device, the device including a substrate, a computational device mounted on the substrate, with a first surface of the substrate having one or more nanoelements formed within, the one or more nanoelements having a diameter of 100 nm-5,000 nm. In some embodiments, a heat dissipator may be mounted on the substrate, the heat dissipator having at least one nanostructure, and the one or more nanoelements forming a thermal conductive pathway between the computational device and the heat dissipator. In some embodiments, the substrate is a silicon substrate. In some embodiments, the nanoelements extend to a depth of 10 to 15 microns within a silicon substrate. In some embodiments, a through-via extends between the first surface of the substrate and a second surface of the substrate, the second surface opposite the first surface. In some embodiments, the one or more nanoelements may form a ring around the through-via, the ring having a diameter of 10 to 50 microns. In some embodiments, the first surface of the substrate includes at least one nanoelement with a size in the range of 100 nm to 5,000 nm. In some embodiments, the one or more nanoelements may include a material differing from the substrate. In some embodiments, the one or more nanoelements may include one or more nanoholes, and the one or more nanoholes may be filled with a metal plug.

An example embodiment provides a system, the system includes a substrate having a first surface, a computational device mounted on the substrate, and at least one nanoelement with a diameter in the range of 100 nm to 5,000 nm formed on the first surface. In some embodiments, the substrate is a silicon substrate, and in some embodiments, the at least one nanoelement includes silicon. In some embodiments, the at least one nanoelement forms a randomly oriented patterned nanostructure. In some embodiments, the at least one nanoelement includes at least a first nanoelement having a first size and a first shape and a second nanoelement having a second size and a second shape, the first shape differing from the second shape and the second size differing from the first size. In some embodiments, a metal layer may coat a surface of the at least one nanoelement to form a thermal conductive pathway. In some embodiments, the first surface of the substrate includes one or more nanoholes having a diameter of 100 nm to 5,000 nm, and a metal layer may coat a surface of the at least one nanoelement and plug the one or more nanoholes. In some embodiments, a through-via may extend between the first surface of the substrate and a second surface of the substrate opposite the first surface. In some embodiments, a heat dissipator may be mounted on the first surface of the substrate, the heat dissipator may include at least a third nanoelement, the at least one nanoelement may form a nanostructure on the first surface of the substrate, and one or more nanoholes and the nanostructure may form a thermal conductive path from the through-via to the heat dissipator. In some embodiments, the at least one nanoelement forms a nanostructured surface over the first surface of the substrate, and the surface area of the nanostructure surface is at least 10 times the surface area of the first surface.

An example embodiment provides a method, the method may provide forming a through-via on a substrate, forming one or more nanoelements on a first surface of the substrate around the through-via on the substrate, and forming a metal plug within the through-via. In some embodiments, forming the through-via may be performed using a wet-etch process, and forming the one or more nanoelements around the through-via may be performed using a dry-etch process. In some embodiments, forming the one or more nanoelements around the through-via may be performed by forming at least a first set of nanoelements in a ring around the through-via and forming at least a second set of nanoelements in a ring around the first set of nanoelements. In some embodiments, a nanostructure including one or more nanoelements is formed on the first surface of the substrate, and a metal layer is formed over the nanostructure, the metal layer forming a plug in one or more nanoholes. In some embodiments, a heat dissipator may be mounted on the first surface of the substrate, the heat dissipator including at least one nanoelement forming a thermal conductive path between the through-via and the heat dissipator.

### BRIEF DESCRIPTION OF THE DRAWING

In the following section, the aspects of the subject matter disclosed herein will be described with reference to exemplary embodiments illustrated in the figures, in which:

FIG. 1 depicts a cross-section view of an example embodiment of a packaging structure according to various embodiments of the subject matter disclosed herein;

FIG. 2A depicts a cross-section view of an example embodiment of a surface structure according to various embodiments of the subject matter disclosed herein;

FIG. 2B depicts a cross-section view of an example embodiment of a surface structure according to various embodiments of the subject matter disclosed herein;

FIG. 2C depicts a cross-section view of an example embodiment of a surface structure according to various embodiments of the subject matter disclosed herein;

FIG. 2D depicts a cross-section view of an example embodiment of a surface structure according to various embodiments of the subject matter disclosed herein;

FIG. 3A depicts a cross-section view of an example embodiment of a packaging structure according to various embodiments of the subject matter disclosed herein;

FIG. 3B depicts a plan view of an example embodiment of a packaging structure according to various embodiments of the subject matter disclosed herein;

FIG. 4A depicts a cross-section view of an example embodiment of a packaging structure assembly at a first time according to various embodiments of the subject matter disclosed herein;

FIG. 4B depicts a cross-section view of an example embodiment of a packaging structure assembly at a second time according to various embodiments of the subject matter disclosed herein;

FIG. 4C depicts a cross-section view of an example embodiment of a packaging structure assembly at a third time according to various embodiments of the subject matter disclosed herein;

FIG. 4D depicts a cross-section view of an example embodiment of a packaging structure assembly at a fourth time according to various embodiments of the subject matter disclosed herein;

FIG. 4E depicts a cross-section view of an example embodiment of a packaging structure assembly at a fifth time according to various embodiments of the subject matter disclosed herein;

FIG. 4F depicts a cross-section view of an example embodiment of a packaging structure assembly at a sixth time according to various embodiments of the subject matter disclosed herein;

FIG. 5 an example embodiment of a method of forming a package structure according to various embodiments of the subject matter disclosed herein

FIG. 6 depicts a cross-section view of an example embodiment of a packaging structure assembly according to various embodiments of the subject matter disclosed herein;

FIG. 7 depicts a cross-section view of an example embodiment of a packaging structure assembly according to various embodiments of the subject matter disclosed herein; and

FIG. 8 depicts a cross-section view of an example embodiment of a packaging structure assembly according to various embodiments of the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” etc.) may be occasionally interchangeably used with a corresponding non-hyphenated version (e.g., “two dimensional,” “predetermined, etc.), and a capitalized entry (e.g., “Counter Clockwise,” “Three-Dimensional,” etc.) may be interchangeably used with a corresponding non-capitalized version (e.g., “counter clockwise,” “three-dimensional,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms)used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein substrates may refer to a variety of materials and structures, including wafers using silicon, wafers using silicon on an insulator (SOI) such as glass, wafers of other semiconductor materials such as germanium, as well as other semiconductor materials on an insulator. In some embodiments, a substrate may include an organic material. In some embodiments, the substrates may be referred to as wafers, dies, and chips alone or in combination. Bonding substrates may be thus known in some embodiments as die-to-die (D2D) bonding, wafer-to-wafer bonding (W2 W) or die-to-wafer bonding (D2 W). In some embodiments, the substrates may contain circuits such as integrated circuits including central processing units (CPUs), logic chips, memory such as static random-access memory (SRAM), dynamic random-access memory (DRAM), synchronous dynamic random-access memory (SDRAM), double data rate DRAM or DDR DRAM, application processors (AP), graphical processing units (GPUs), other forms of auxiliary processing units (xPU), Artificial intelligence (AI) chips, high bandwidth memory (HBM) interfaces, and other application-specific integrated circuits (ASIC). In some embodiments, a combination of circuits may be present on a substrate. In some embodiments, a substrate may include a packaged chip.

As used herein, high bandwidth memory or HBM, may refer to a chip structure including one or more HBM modules. In some embodiments, the HBM may be manufactured by an advanced silicon node process.

As used herein packaging refers to a process of forming interconnections between substrates. In some embodiments, the interconnections may be between direct surfaces and involve W2 W, D2D, and D2 W bonding. In other embodiments, techniques including wire bonding and other forms of indirect bonding may be performed alone or in combination with W2 W, D2D, and D2 W bonding. In some embodiments, circuits may be bonded directly facing each other, while in other embodiments a flip-chip bonding may be used. In some embodiments, interconnections may be made between substrates on a front or circuit side of the substrate. In other embodiments, interconnections may be made on a rear or back side of the substrate opposite from the circuit structure. In some embodiments, an interconnection may include through-silicon vias (TSVs) or other forms of through-chip vias where one or more substrates may be connected using a via traveling through an interposer such as another substrate or chip. In some embodiments, an interconnection may be formed using connections on a surface of a substrate, such as a pad, and may use additional materials between the pads such as solder to form an interconnection.

As used herein, conductors may refer to a variety of conductive materials, including which materials may be used alone or in combination with other materials such as in the form of an alloy. In some embodiments the conductor is copper (Cu). In some embodiments, copper (Cu) may be in the form of Cu (II), Cu (III) or other forms of copper, alone or in combination with additional elements, including cobalt (Co) and ruthenium (Ru). Such a listing of elements is not intended to be exhaustive, and in other embodiments, any known other type of conductive material may be used.

As used herein, a system-on-a-chip or SOC refers to an integrated circuit that integrates most or all components of a computer into a single die. In some embodiments, the components may include on-chip CPU, memory interfaces, input/output (I/O) devices and interfaces, secondary storage interfaces, and may include other components such GPUs. In some embodiments a SOC may contain digital, analog, mixed-signal, and radio frequency signal processing functions. In some embodiments, the SOC may be manufactured by processes including an advanced silicon node process.

As used herein, nanomaterials refers to materials having an external dimension or internal structure in the nanoscale region. The nanoscale region may be defined as the region below 1 micron, also known as the submicron region. Nanomaterials may include materials having structural elements that are in the range between 0.1 nm and 5,000 nm. As used herein, nanostructures refer to structures whose individual structural elements are in the nanoscale region, i.e., in the range between 0.1 nm and 5,000 nm. Nanoparticles may include materials in particle form having a size in the range between 0.1 nm and 5,000 nm.

As used herein, size may be used to refer to an approximate diameter, width, thickness, diagonal, or other dimension which has the longest distance within a planar view. As used herein, diameter, when referring to nanoholes may refer alternatively to the length of a diagonal direction within the surface plane the nanoholes are formed in. For example, in some embodiments, the diameter of a nanohole may refer to the diameter of a circular nanohole, the length of the major or semi-major axis of an elliptical nanohole, the diagonal width of a rectangular nanohole, and other similar measures.

As used herein, ceramics refers to inorganic, non-metallic materials. In some embodiments, ceramic materials may include metallic oxides, including aluminum oxide, Al₂O₃, beryllium oxide, BeO, nitrides such as silicon nitride, Si₃N₄, aluminum nitride, AlN, and carbides such as silicon carbide, SiC, and any combination thereof.

Disclosed herein are various embodiments of devices, systems and methods related to packaging architecture and the use of radiative nanostructures and nanomaterials. In some embodiments, nanostructures may be formed on a surface of a semiconductor package structure. A semiconductor package structure may include one or more computational devices mounted on a substrate, with heat conductive structures such as a heat sink or a heat dissipater having a thermal connection with the one or more computational devices. In some embodiments, nanostructures may be formed on one or more surface areas of the semiconductor package structure. In some embodiments, nanostructures may be further patterned to form a plurality of nanostructures, having individual elements between 10 nm and 50 nm. A nanostructure may provide an increase in the radiative heat transferred from the surface areas of the semiconductor package structure. In some embodiments, nanostructures may be formed within the surface of a semiconductor substrate, additionally or alternatively in some embodiments, nanostructures may be formed on an interposer structure supporting a semiconductor substrate. In some embodiments, the nanostructure may be formed of silicon (Si) and may be formed over the surface of a silicon substrate. In some embodiments, a silicon nanostructure may be referred to as black silicon. In some embodiments, a black silicon layer may include one or more nanoelements formed on or within a substrate, and may include one or more nanosized elements having one or more of pillars, spike, intrusions, cones or other suitable configurations. In some embodiments, a semiconductor substrate with a black silicon layer on the substrate may be further patterned to include a plurality of nanoelements, having a diameter of about 100 nm to 5,000 nm, or may have diameter of about 10 nm to about 500 nm. In some embodiments, the plurality of nanoelements may be organized in a pattern having a size of about 10 to 50 microns. In some embodiments, the plurality of nanoelements may have a depth of 10-15 microns, or as much as about 20 microns. In some embodiments, the plurality of nanoelements may have a height of 10-15 microns, or as much as about 20 microns. In some embodiments, the plurality of nanoelements may be formed around a TSV, and in some embodiments, the plurality of nanoelements may form a ring around a TSV In some embodiments, a black silicon surface may have a plurality of holes formed therein, with a layer of metal such as aluminum deposited over the black silicon surface and the plurality of holes. In some embodiments, a semiconductor substrate with a plurality of holes having a diameter of about 100 nm to 5,000 nm may be referred to as a holey silicon. In some embodiments, a black silicon layer may be formed on holey silicon. In some embodiments, nanostructures may be formed within a heat sink or a heat dissipater.

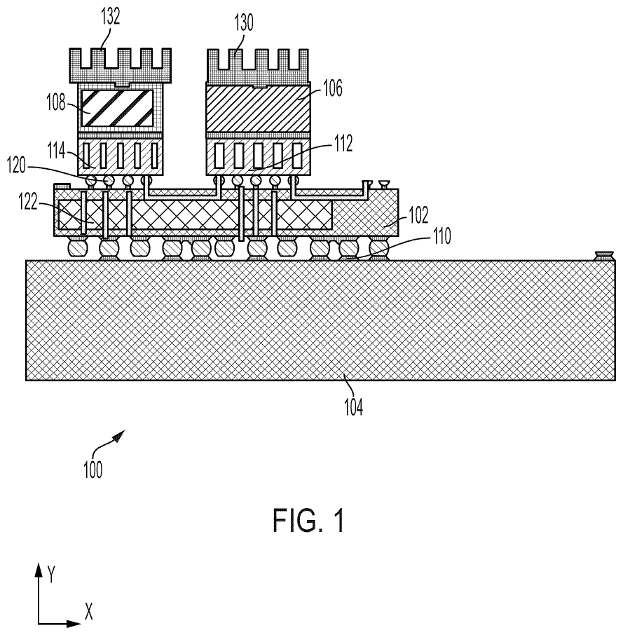

FIG. 1 depicts a perspective view of an exemplary embodiment of a first package architecture 100 which may incorporate the nanomaterials disclosed herein. A base substrate 102 supports at least a first computational device 106 and a second computational device 108 (each also referred to herein generically as a “device” or “computational device” and, collectively, as “computational devices”). In some embodiments, the computational devices may include a processor die, or a processor chiplet. In some embodiments, the computational devices may be various forms of memory including DRAM, SRAM, and other forms of memory. In some embodiments, the computational devices may include a core computational device, for example a processor or other form of microcontroller to act as a controller. In some embodiments, the first computational device 106 and a second computational device 108 may each comprise a stack of one or more component computational devices. In some embodiments, additional computational devices may be mounted on the base substrate 102 in addition to the first computational device 106 and the second computational device 108. In some embodiments, only a single computational device may be mounted on the base substrate 102. In some embodiments, a photonic integrated circuit, PIC, may be mounted on the base substrate 102, with the PIC coupled to transmit a signal to the first computational device 106 and/or the second computational device 108.

In some embodiments, the base substrate 102 may be a silicon die, while in other embodiments a variety of semiconductor materials may be used, either alone or in combination. For example, in some embodiments, the base substrate 102 may comprise a SOI substrate such as glass, as well as a germanium, sapphire or other form of semiconductor, either alone, in combination with another semiconductor, or with an insulator such as glass.

The base substrate 102 may be mounted on a supporting substrate 104. In some embodiments, the supporting substrate 104 may take the form of a die, a wafer, an organic substrate, a printed circuit board, a card, or any other known suitable substrate. A substrate interface structure 110 may form a connection (i.e., a physical and electrical connection) between the supporting substrate 104 and the base substrate 102. In some embodiments, a connection may be formed between the substrate interface structure 110 and wiring layers 122, which may transmit electrical signals including power and communications signals between the wiring layers 122 and the supporting substrate 104.

The substrate interface structure 110 may include a conductive connection, such as a bumps, microbumps, pillars, balls, and other forms such as controlled-collapse chip connection (C4) bumps, alone or in combination. As used herein, a C4 bump refers to a form of solder bumps placed on pads on a top surface of a substrate prior to flipping the substrate to form a flip-chip. The substrate interface structure 110 may further include a dielectric material, which may include a material such as an adhesive, resin, or elastomer which may form a connection between the base substrate 102 and the supporting substrate 104 in addition to a conductive connection. In some embodiments, the dielectric material may take the form of an underfill material. In some embodiments, the combination of a conductive connection and a dielectric connection may form a hybrid bond.

Although referred to as wiring layers 122, one or more of the wiring layers 122 may take the form of series of pads, bumps, vias, through-vias, traces, redistribution layers and other forms of conductive connections for redistributing signals in various combinations. Similarly, the redistribution layers may also take the form of series of pads, bumps, vias, through-vias, traces, redistribution layers and other forms of connection for redistributing signals in various combinations.

The conductive connection of the substrate interface structure 110 may transmit power and communication signals between the supporting substrate 104 and the base substrate 102. The electrical signals in the substrate interface structure 110 may then produce heat as a result of resistance within the conductive connection. Heat may also be produced within the wiring layers 122 from the resistance within the wiring layers 122 to the electrical signals being transmitted. In some embodiments, where the wiring layer 122 includes a TSV or other conductive connections embedded in the base substrate 102, heat may be produced within the base substrate 102.

In some embodiments, the wiring layers 122 may further connect to the base substrate 102 to the first computational device 106 and the second computational device 108 via a device interface structure 120. The wiring layers 122 may be part of an exchange of electrical power and communication signals between the supporting substrate 104, the base substrate 102, and the first computational device 106 and the second computational device 108. In some embodiments, the base substrate 102 may include logic circuits allowing routing between the first computational device 106, the second computational device 108, as well as any other computational devices mounted in connection with the base substrate 102 and the supporting substrate 104. In some embodiments, a PIC may be connected to the wiring layers 122 to couple power and data signals between the first computational device 106 or the second computational device 108 and the PIC.

The device interface structure 120 may include a conductive connection, such as a bumps, microbumps, pillars, balls, and other forms such as C4 bumps, alone or in combination. The device interface structure 120 may further include a dielectric material, which may include a material such as an adhesive, resin, or elastomer which may form a connection between the base substrate 102, the first computational device 106 and second computational device 108 in addition to a conductive connection. In some embodiments, the dielectric material may take the form of an underfill material. In some embodiments, the combination of a conductive connection and a dielectric connection may form a hybrid bond.

In some embodiments, the first computational device 106 may have a first heat dissipator 112. In some embodiments, the second computational device 108 may have a second heat dissipator 114. In some embodiments, such as in the exemplary embodiment of FIG. 1, a heat dissipator may be positioned between a computational device and the base substrate 102, where the first heat dissipator 112 is between the first computational device 106 and the base substrate 102, and the second heat dissipator 114 is between the second computational device 108 and the base substrate 102. In some embodiments, in addition or in alternative to positioning a heat dissipator between a computational device and the base substrate 102, a heat dissipator may be mounted the sides or top of the computational device. In the exemplary embodiment of FIG. 1, placing the first heat dissipator 112 between the base substrate 102 and the first computational device 106 provides a thermal conductive pathway for heat from the base substrate 102, the first computational device 106, and the device interface structure 120 to transfer out of the first package architecture 100. In some embodiments, a heat dissipator may be made of a thermally conductive material, such as a metal like copper or aluminum, as well as any other known suitable material. A high thermal conductivity may allow heat to transfer via conduction from surrounding materials into the heat dissipator. In some embodiments, a thermal conductive pathway may extend between a heat generating element on the base substrate 102 to a heat dissipator such as the first heat dissipator 112. In some embodiments, a heat dissipator may then transfers the heat from the heat dissipator into the surrounding environment. For example, in some embodiments, a heat dissipator integrated in heat sink may conduct heat into a fluid, such as air or water, where the heat may be transferred away from the heat sink using convective heat transfer. In some embodiments, the fluid may flow passively, while in other embodiments, an active device such as a pump or fan, or any other known form of fluid transfer device, may cause the fluid to move. In addition, or alternatively, a heat dissipator integrated in a heat sink may transfer heat radiatively, where the surface of the heat sink transfers heat using electromagnetic radiation, as excess thermal energy causes photonic emission from a hot surface. In radiative heat transfer, the heat may be either reabsorbed by surrounding environmental conditions, or may be transmitted into space. As such, in some embodiments, conductive, convective, and radiative heat transfer may each transfer heat from a heat sink.

In some embodiments, a first heat sink 130 may be mounted on top of the first computational device 106, and a second heat sink 132 may be mounted on top of the second computational device 108. In some embodiments, a heat sink may be mounted on additional surfaces of the first package architecture 100, and may include mounting a heat sink on the side, top or bottom surfaces of the first computational device 106, the second computational device 108, first heat dissipator 112, the second heat dissipator 114, the base substrate 102 or the supporting substrate 104. In some embodiments, a heat sink as discussed herein may incorporate a heat dissipator as discussed herein. In some embodiments, a heat sink such as the first heat sink 130 or the second heat sink 132 may conduct heat into a fluid, such as air or water, where the heat may be transferred away from the heat sink using convective heat transfer. In some embodiments, the fluid may flow passively, while in other embodiments, an active device such as a pump or fan, or any other known form of fluid transfer device, may cause the fluid to move. Exemplary heat sinks may transfer heat to ambient by a combination of radiative and convective heat transfer to the ambient environment, with contribution of the radiative heat transfer being based at least in part on the emissivity of the heat sink.

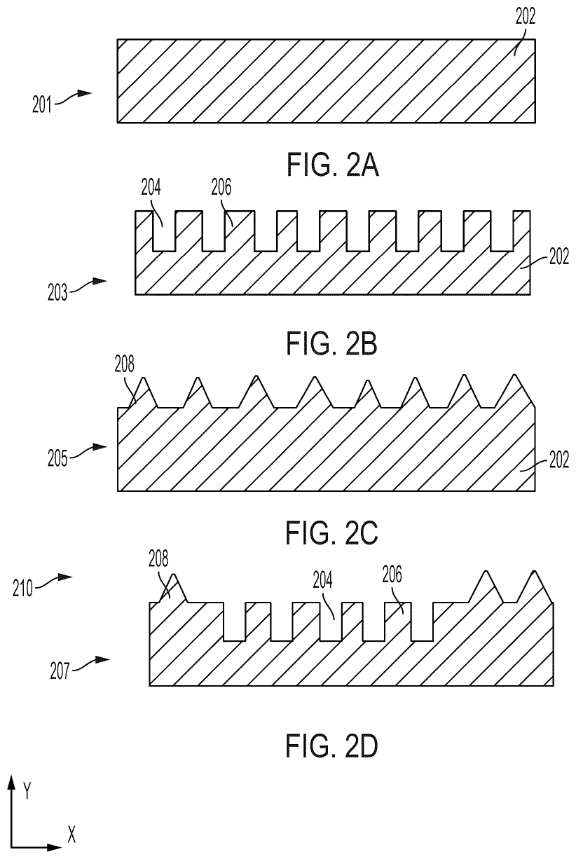

FIG. 2A depicts an example embodiment of a cross-sectional view of a first configuration 201 of a nanostructure substrate 202. In some embodiments, the nanostructure substrate 202 may be used in a package architecture such as the first package architecture 100 in FIG. 1, and may be used as the base substrate 102, the supporting substrate 104, the first heat dissipator 112, the second heat dissipator 114, the first heat sink 130, the second heat sink 132, or any other suitable surface of the first package architecture 100. In other embodiments, the nanostructure substrate 202 may be used with any suitable configuration. FIG. 2A provides an example of where the surface of the nanostructure substrate 202 is effectively planar. Although shown in FIG. 2A as a solid layer, the nanostructure substrate 202 may vary. In some embodiments, the nanostructure substrate 202 may be a semiconductor substrate material, including materials such as silicon or germanium, while in some embodiments the nanostructure substrate 202 may comprise a SOI substrate such as glass, as well as a germanium, sapphire or other form of semiconductor, either alone, in combination with another semiconductor, or with an insulator such as glass. In some embodiments, additional layers may form on the surface of nanostructure substrate 202, either by deliberate use of semiconductor processing, such as diffusion, deposition, or electroplating, or may form naturally from exposure to atmosphere, for example a silicon substrate may form a layer of silicon oxide, although other oxides and materials may form. In some embodiments, the nanostructure substrate 202 may be subject to a planarization process, such as grinding, polishing, and techniques such as chemical-mechanical planarization (CMP). In other embodiments, the layer may have a surface roughness, which in some embodiments may be caused by non-uniformities in the formation of the nanostructure substrate 202, or a layer thereon. In some embodiments, a process may deliberately increase the surface roughness of a layer, for example by using a process such as etching or a deposition process, although any other suitable technique may be created.

FIG. 2B depicts an exemplary embodiment of a second configuration 203 for the nanostructure substrate 202. In the second configuration 203, unlike the example of the first configuration in FIG. 2A, the surface of the nanostructure substrate 202 has been processed to form one or more nanoholes 204, with one or more plateaus 206 shown between the one or more nanoholes 204. In some embodiments, the one or more nanoholes 204 are formed within the surface of the nanostructure substrate 202, while in other embodiments, the one or more nanoholes 204 may be formed in a surface layer on the nanostructure substrate 202. In some embodiments, the one or more nanoholes 204 may have a depth of 10-15 microns, but in some embodiments, the depth may vary to 20 microns or larger, or 5 microns or smaller. The process to form the one or more nanoholes 204 may be any suitable process to pattern a surface, including lithography, grinding, polishing, pressing, etching into the surface, as well as deposition techniques such as ALD, PVD, CVD, and molding to build up on a surface, either alone or in combination.

In some embodiments, the one or more nanoholes 204 may have a diameter in the range of 100-5,000 nm, although in some embodiments, the diameter may be smaller or larger, for example, some embodiments may have a diameter in the range of 1,000-3,500 nm. In some embodiments, such as the exemplary embodiment of FIG. 2B, the one or more nanoholes 204 may be shaped as a rectangular prism, while in others the one or more nanoholes 204 may be shaped in any suitable form, such as pyramids, cylinders, hemispheres, as well as irregular shapes. In some embodiments, the one or more nanoholes 204 may have uniforms shapes and sizes, while in other embodiments, the one or more nanoholes 204 may have a plurality of shapes and sizes. In some embodiments, the one or more nanoholes 204 may have a uniform depth, while in other embodiments, the depth may vary between the one or more nanoholes 204, additionally or alternatively, the depth may vary within one of the one or more nanoholes 204.

In some embodiments, the one or more plateaus 206 and the one or more nanoholes 204 may form a repeating pattern, such as a ring, square, or any other suitable shape, while in other embodiments, the one or more nanoholes 204 may be randomly aligned. In some embodiments, the one or more nanoholes 204 and the one or more plateaus 206 may have regular spacing, while in other embodiments, the spacing between the one or more nanoholes 204 may vary. In some embodiments, the one or more nanoholes 204 and the one or more plateaus 206 may have the same orientation, while in other embodiments the orientation of the one or more nanoholes 204 may vary. As used herein, the second configuration 203 may also be referred to as holey silicon or HSi. In some embodiments, the one or more nanoholes 204 may be formed as a thermal meta-lens, where the one or more nanoholes 204 increase the thermal conductivity of phonons traveling within the nanostructured substrate, and allow for the creation of heat-lensing patterns.

FIG. 2C depicts an exemplary embodiment of a third configuration 205 for the nanostructure substrate 202. In the third configuration 205, unlike the first configuration 201 of FIG. 2A or the second configuration 203 of FIG. 2B, one or more nanopillars 208 are formed on top of the surface of the nanostructured substrate 202. In the exemplary embodiment of FIG. 2C, the one or more nanopillars 208 are shown having a triangular cross section, while the one or more valleys are shown as a flat area between the one or more nanopillars 208. However, the shape, size, uniformity, spacing, patterning, and orientation of the one or more nanopillars 208. In some embodiments, the one or more nanopillars 208 may have a diameter in the range of 100-5,000 nm, although in some embodiments, the size may be smaller or larger, for example, some embodiments may have a diameter in the range of 1,000-3,500 nm. In some embodiments, such as the exemplary embodiment of FIG. 2C, the one or more nanopillars 208 may be shaped as a pyramid, while in others the one or more nanopillars 208 may be shaped in any suitable form, such as prisms, cylinders, hemispheres, spikes, as well as irregular shapes. In some embodiments, the one or more nanopillars 208 may have uniforms shapes and sizes, while in other embodiments, the one or more nanopillars 208 may have a plurality of shapes and sizes. In some embodiments, the one or more nanopillars 208 may have a regular spacing, while in other embodiments, the one or more nanopillars 208 may have an irregular spacing, while still other embodiments may have the one or more nanopillars 208 with a random spacing. In some embodiments, the one or more nanopillars 208 may have the same orientation, while in other embodiments the orientation of the one or more nanopillars 208 may vary. In some embodiments, the one or more nanopillars 208 may form a randomly oriented patterned nanostructure. As used herein, the third configuration 205 may also be referred to as black silicon or BSi. In some embodiments, the third configuration 205 may increase the effective surface area as much as between 10-fold and 50-fold over the flat surface of the first configuration 201, while in other embodiments the relative increase in surface area may be larger or smaller. In some embodiments, an increase in surface area may provide an increase in thermal emission and thermal conductivity.

The process to form the one or more nanopillars 208 may be any suitable process to pattern a surface, including lithography, grinding, polishing, pressing, etching into the surface, as well as deposition techniques such as ALD, PVD, CVD, and molding to build up on a surface, either alone or in combination.

FIG. 2D depicts an exemplary embodiment of a fourth configuration 207 for the nanostructure substrate 202. The fourth configuration 207 of FIG. 2D differs from the second configuration 203 and the third configuration 205 by including the one or more nanoholes 204, the one or more the plateaus 206 and the one or more nanopillars 208. The one or more nanoholes 204, the one or more plateaus 206 and the one or more nanopillars 208 may be collectively referred to as one or more nanoelements 210. The number, layout, size, spacing, and orientation of the one or more nanoholes 204 and the one or more nanopillars 208 may be uniform or may vary as discussed above with the exemplary embodiments of FIG. 2B and FIG. 2C. Furthermore, the layout of the third nanostructure 307 may be regular, irregular, or random.

The formation of a nanostructure on surface of the nanostructure substrate 202 may increase the surface area on the nanostructure substrate 202 without an increase in volume. Such an increase in surface area may increase the effective emissivity of the nanostructure substrate 202. In some embodiments, forming a nanostructure on the nanostructure substrate 202 may increase the emissivity of the package surface by up to 5 times or more compared to an unstructured surface, while in other embodiments the emissivity increase may be higher or lower compared to an unstructured surface. In some embodiments, the relative cooling experienced by a computational device using such a nanostructure may be greater than 30° C. compared to an unstructured surface, while in other embodiments the cooling increase compared to an unstructured surface may vary and be higher or lower than 30° C. In some embodiments, the emissivity of a device using such a nanostructure may have an emissivity value of F greater than 0.2 (ε>0.2), while in some embodiments the emissivity value may be greater than 0.5 (ε>0.5), greater than 0.75 (ε>0.75), or greater than 0.8.5 (ε>0.85). In some embodiments, the emissivity value of a silicon nanostructured substrate 202 of the third configuration 205 may be equal to 0.88 (ε=0.88), which may be a 5.7-fold increase than over the emissivity value of the first configuration 201 of 0.16 (ε=0.16). In some embodiments, the emissivity values may be higher or lower than 0.88.

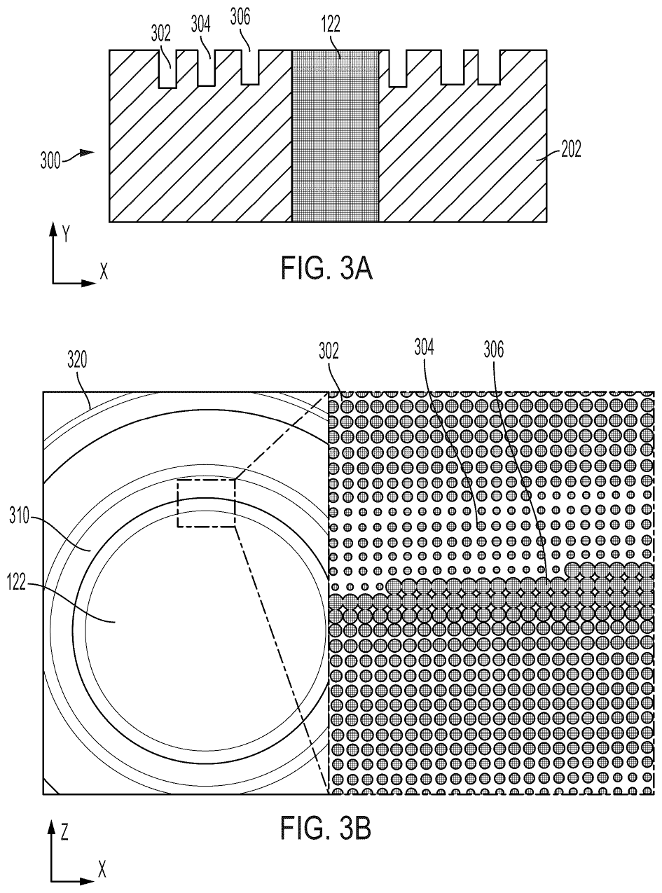

FIG. 3A depicts an exemplary embodiment of a cross-sectional view of a cooling nanostructure 300. FIG. 3A, unlike FIGS. 2A-2D, has wiring layer 122 as a conductive wire in a through-via penetrating the nanostructure substrate 202. The wiring layer 122 may carry electrical signals such as power or data signals to other elements mounted on the nanostructure substrate 202, or may connect to elements on additional substrates the nanostructure substrate 202 connects to. As electrical signals travel along the wiring layer 122, heat may be produced due to resistance within the wiring layer 122. In some embodiments, the heat from the wiring layer 122 may transfer to the nanostructure substrate 202 via conductive heat transfer. In some embodiments, heat transferred to the nanostructure substrate 202 may then potentially be thermally conducted to other elements attached to the nanostructure substrate 202, such as memory devices, processors, and other chips. In some embodiments, the cooling nanostructure 300 may assist in forming a path of thermal conduction, while in other embodiments, the cooling nanostructure 300 may increase the radiative cooling of the nanostructure substrate 202, or may provide a combination of both.

FIG. 3B depicts an exemplary embodiment of a plan view of the cooling nanostructure 300 shown in FIG. 3A. FIG. 3A and FIG. 3B show a first ring 310 of nanoelements formed around the wiring layer 122, with a first set of nanoelements 302 distal from the wiring layer 122, a third set of nanoelements 306 proximal to the wiring layer 122, and a second set of nanoelements 304 between the first set of nanoelements 302 and the third set of nanoelements 306. The nanoelements forming the first set of nanoelements 302, the second set of nanoelements 304, and the third set of nanoelements 306 may be one or more of the nanoholes 204, the one or more plateaus 206, and the nanopillars 208 as previously discussed with respect to FIGS. 2A-2D, the second configuration 203, the third configuration 205, and the fourth configuration 207. In some embodiments, multiple sets of rings of nanoelements may be formed, with FIG. 3B providing a second ring 320, which may include one or more additional sets of nanoelements. In some embodiments, the nanoelements forming the first set of nanoelements 302, the second set of nanoelements 304, and the third set of nanoelements 306 may be formed of the just one type of the nanoelements 210, while in other embodiments, the nanoelements forming the first set of nanoelements 302, the second set of nanoelements 304, and the third set of nanoelements 306 may be formed from a combination of the types of the nanoelements 210.

In some embodiments, the configuration of the nanoelements forming the first set of nanoelements 302, the second set of nanoelements 304, and the third set of nanoelements 306 may provide an increase in thermal conductivity within the nanostructure substrate 202. In some embodiments, the cooling nanostructure 300 may pattern the first set of nanoelements 302, the second set of nanoelements 304, and the third set of nanoelements 306 to provide a thermal lensing or focusing effect and direct heat in a specific direction. In some embodiments, the nanostructure substrate 202 may have an increase of thermal conductivity of 4-fold or higher due to the presence of nanoelements, although in some embodiments, the increase of thermal conductivity may be higher or lower. Such an increase of thermal conductivity may be used to form one or more thermal conductive pathways on the cooling nanostructure 300, and may be used to conduct heat from sensitive parts of a semiconductor package, such as computational devices, towards heat dissipators, heat sinks or non-sensitive portions of the package. In some embodiments, the increase in thermal conductivity may be combined with an increase of thermal emissivity and increase radiative heat transfer from the cooling nanostructure 300.

In some embodiments, a heat dissipator may include one or more nanoelements, and the one or more nanoelements may increase the radiative heat transfer from the heat dissipator. In some embodiments, one or more of the nanoelements forming the first set of nanoelements 302, the second set of nanoelements 304, and the third set of nanoelements 306 may form a heat dissipating surface, where heat produced within the wiring layer 122 may be both conducted by the nanoelements away from the through-via within the nanostructured substrate 202, as well as radiated away from the nanostructured substrate 202. In some embodiments, the heat dissipator may be formed by one or more nanoelements, the one or more nanoelements forming a nanostructure.

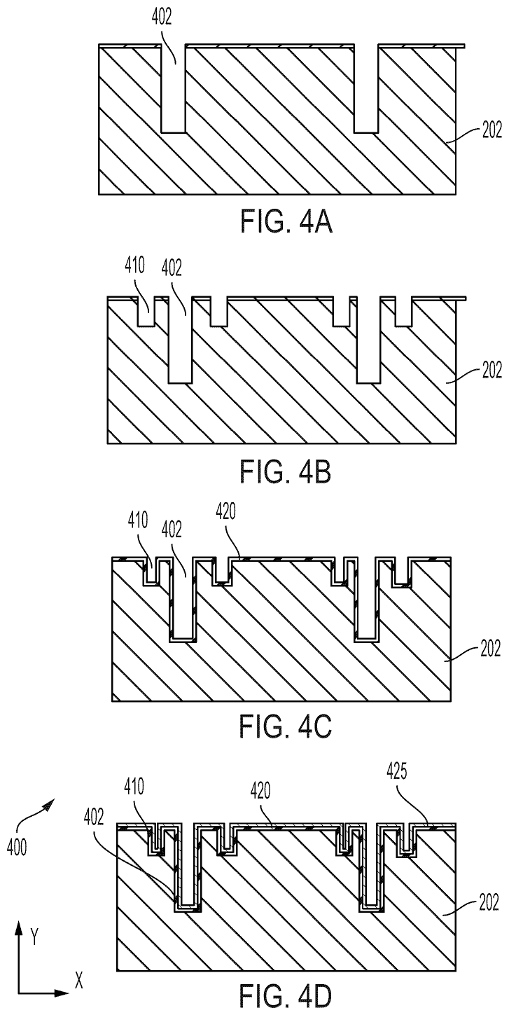

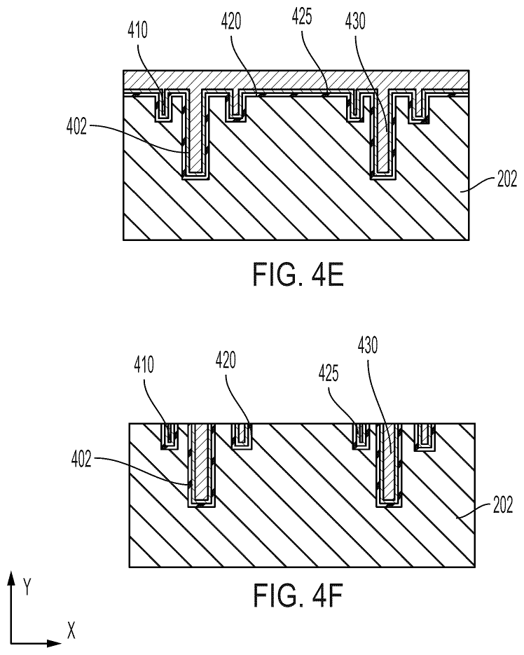

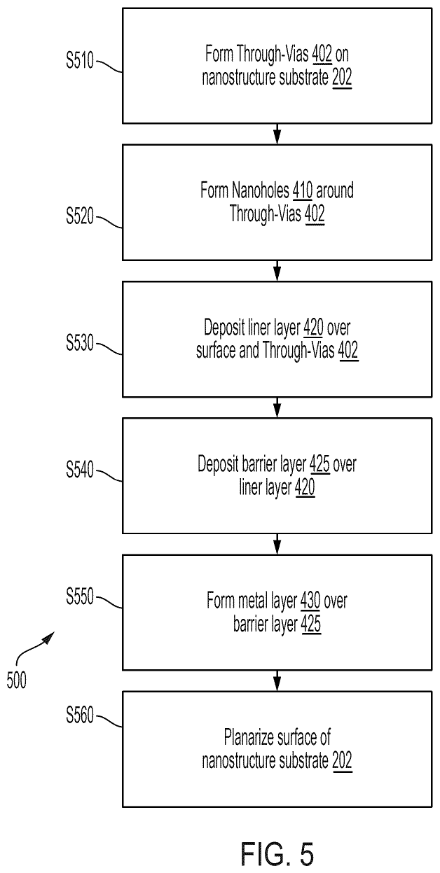

FIGS. 4A-4F depict an illustrative embodiment of a method of forming nanoelements of a process substrate 400. FIG. 5 depicts an example embodiment of a process 500 for forming a process substrate corresponding to the illustrative embodiment of FIGS. 4A-4F. The process substrate 400 may take the form of the nanostructure substrate 202 or the cooling nanostructure 300. The process 500 may, in some embodiments, take place during a larger processing process, such as the formation of interconnections and wiring layers on a substrate, such as those of wiring layers 122 of FIG. 1. In other embodiments, the steps of the process substrate 400 may take place during a separate processing step.

FIG. 4A depicts at S510 in FIG. 5 an exemplary embodiment of the formation of through-vias 402 within the nanostructure substrate 202. The through-vias 402 may be formed using any suitable semiconductor process, and may include techniques such as etching, including both wet-etch processes using chemicals and dry-etch processes using reactive plasma, as well as lithography, mechanical drilling, lasers, and a combination of these methods and any other suitable methods known in the art. In some embodiments, the through-vias 402 may be formed isotropically, while in other embodiments, the through-vias 402 may be formed anisotropically, and in some embodiments, the through-vias 402 may be formed using a combination of isotropic and anisotropic means. In some embodiments, a photo-resist mask may be deposited on the nanostructure substrate 202 and selectively patterned using photolithography prior to applying an etch. In some embodiments, a mask may protect unreacted portions of the nanostructure substrate 202 from being unnecessary etched, and such a mask may be removed after the formation of the through-via 402, such as by applying a solvent, or other suitable cleaning process. In some embodiments, the through-vias 402 may be formed to have a depth of the entire nanostructure substrate 202, while in other embodiments, the through-vias 402 may be formed to have a depth of part of nanostructure substrate 202.

FIG. 4B depicts at S520 in FIG. 5 an exemplary embodiment of the formation of one or more nanoholes 410 at locations around the through-vias 402. In some embodiments, the one or more nanoholes 410 may be the one or more nanoholes 204 as discussed above. The one or more nanoholes 410 may be formed using any suitable semiconductor process, and may include techniques such as etching, including both wet etch processes using chemicals and dry-etch processes using reactive plasma, as well as lithography, mechanical drilling, lasers, and a combination of these methods and any other suitable methods known in the art. In some embodiments the one or more nanoholes 410 may be formed isotropically, while in other embodiments, the one or more nanoholes 410 may be formed anisotropically, and in some embodiments, the one or more nanoholes 410 may be formed using a combination of isotropic and anisotropic means. In some embodiments, a mask may protect unreacted portions of the nanostructure substrate 202 from being unnecessary etched, and such a mask may be removed after the formation of the one or more nanoholes 410, such as by applying a solvent, or other suitable cleaning process. In some embodiments, a dry etch using a plasma may be applied to form the one or more nanoholes 410 by etching a hole within the nanostructure substrate 202. In some embodiments, the one or more nanoholes 410 may be formed to have a depth of 10-15 microns, while in other embodiments, the depth may vary to be greater or smaller. In some embodiments, the one or more nanoholes 410 may be formed to have a diameter of 100 nm to 5,000 nm, while in other embodiments, the diameter may vary to be greater or smaller. In some embodiments, the one or more nanoholes 410 may be formed in a pattern around the through-vias 402, while in other embodiments, the one or more nanoholes 410 may be formed randomly, or in a pattern not centered around the through-vias 402. In some embodiments, the one or more nanoholes 410 may be formed as a thermal meta-lens, where the one or more nanoholes 410 increase the thermal conductivity of phonons traveling within the nanostructured substrate, and allow for the creation of heat-lens. Furthermore, in some embodiments, the formation of through-vias 402 at S510 and the formation of the one or more nanoholes 410 at S520 may happen in parallel, while in other embodiments, their formation may happen in series.

FIG. 4C depicts at S530 in FIG. 5 an exemplary embodiment of the formation of an liner layer 420 over the surface of the nanostructure substrate 202, as well as in the through-vias 402. The liner layer 420 may be formed from a dielectric material, such as an oxide or nitride, or other suitable material. In some embodiments, the liner layer 420 may provide for an insulator layer between the material of the nanostructure substrate 202 and layer metallic layers, while in other embodiments, the liner layer 420 may protect against electromigration of metal layers, provide protection for corrosion, or provide a compatible surface for additional layers. The liner layer 420 may be formed, for example, in some embodiments by deposition using a CVD process or ALD process such as reacting silane gas, SiH₄, to form a silicon layer followed by an oxidizing gas to form silicon dioxide, SiO₂, while in other embodiments the method of formation and the resulting liner material may vary. For example, in some embodiments, the liner layer 420 may be an oxide layer formed using a diffusion process to cause the conversion of a semiconductor substrate into an oxide, and may include semiconductor materials other than silicon such as germanium, while in other embodiments a combination of methods may be used. The liner layer 420 may be used to create an insulator layer for the through-via 402, and in some embodiments, the liner layer 420 may have a greater dielectric constant than the semiconductor substrate forming the nanostructure substrate 202. In some embodiments, the liner layer 420 may be used to prepare a surface for metalizing the through-vias 402, for example, by forming a surface where a metal may more easily bond than the semiconductor substrate forming the nanostructure substrate 202. In some embodiments, the liner layer 420 may be used for a combination of purposes including those listed above and any other suitable purpose.

In some embodiments, the liner layer 420 may be formed over or within the one or more nanoholes 410, while in some embodiments, a protective mask may be formed over the one or more nanoholes 410 to prevent the liner layer 420 from forming over or within the one or more nanoholes 410. In some embodiments, the liner layer 420 may be deposited over or within the one or more nanoholes 410 and then later removed using a method such as those discussed with respect to S520, as well as any other suitable method of forming a hole. In some embodiments, the liner layer 420 may form a conformal coating over the surface of the nanostructure substrate 202.

FIG. 4D depicts at S540 in FIG. 5 an exemplary embodiment of the formation of a barrier layer 425 over the liner layer 420. In some embodiments, the barrier layer 425 may be formed using a method such as electroplating, PVD, CVD, ALD, as well as any other suitable method alone or in combination. In some embodiments, the barrier layer 425 may be formed of copper, tungsten, aluminum, titanium, as well as any other suitable metal alone or in combination. In some embodiments, the barrier layer 425 may be formed of a metal. In some embodiments, the barrier layer 425 may include one or more additional layers formed to better bond the metal to the semiconductor substrate forming the nanostructure substrate 202, and may include additional metals or non-metals suitable for such a layer, such as nitrides and silicides. In some embodiments, the barrier layer 425 may form a seed layer for a bulk metal layer, while in other embodiments, the barrier layer may form a compatible layer to allow a bulk metal layer to bond to either the semiconductor substrate forming the nanostructure substrate 202 or the liner layer 420. In some embodiments, the barrier layer 425 may form a conformal coating over the liner layer 420, while in some embodiments, the barrier layer 425 may be formed directly on the nanostructure substrate 202.

In some embodiments, the barrier layer 425 may be formed over or within the one or more nanoholes 410, while in some embodiments, a protective mask may be formed over the one or more nanoholes 410 to prevent the barrier layer 425 from forming over or within the one or more nanoholes 410. In some embodiments, the barrier layer 425 may be deposited over or within the one or more nanoholes 410 and then later removed using a method such as those discussed with respect to S520, as well as any other suitable method of forming a hole. In some embodiments, the barrier layer 425 may form a conformal coating over the surface of the nanostructure substrate 202 or the liner layer 420.

FIG. 4E depicts at S550 in FIG. 5 an exemplary embodiment of the formation of a metal layer 430 over the barrier layer 425. In some embodiments, the metal layer 430 may be formed using a method such as electroplating, PVD, CVD, ALD, as well as any other suitable method alone or in combination. In some embodiments, the metal layer 430 may be formed of copper, tungsten, aluminum, titanium, as well as any other suitable metal alone or in combination. In some embodiments, the metal layer 430 may include one or more additional layers formed to better bond the metal to the semiconductor substrate forming the nanostructure substrate 202, and may include additional metals or non-metals suitable for such a layer. In some embodiments, the metal layer 430 may be a bulk layer having a thickness between 10 nm and 10 micron, while in other embodiments, the thickness may be smaller or larger. In some embodiments, patterning step may be used to form a mask on the surface of the nanostructure substrate 202 prior to formation of the metal layer 430, while in other embodiments, a patterning step may take place after the formation of the metal layer 430 to remove excess metal or mask layers, alternatively, in some embodiments patterning may take place prior to and after the formation of the metal layer 430.

In some embodiments, the metal layer 430 may be formed over or within the one or more nanoholes 410, while in some embodiments, a protective mask may be formed over the one or more nanoholes 410 to prevent the metal layer 430 from forming over or within the one or more nanoholes 410. In some embodiments, the metal layer 430 may be deposited over or within the one or more nanoholes 410 and then later removed using a method such as those discussed with respect to S520, as well as any other suitable method of forming a hole. In some embodiments, the formation of the liner layer 420 or the barrier layer 425 may fill the one or more nanoholes 410 and prevent formation of the metal layer 430 within the one or more nanoholes 410. In some embodiments, the formation of the liner layer 420 or the barrier layer 425 may be prevented within the one or more nanoholes 410, while the metal layer 430 may be encouraged to form within the one or more nanoholes 410. In some embodiments, the metal layer 430 may form a plug within the one or more nanoholes 410, while in other embodiments, the metal layer 430 may form a coating of the one or more nanoholes 410. As discussed above, in some embodiments, the formation of one or more nanoholes within the nanostructure substrate 202 may create a thermal meta-lens, where the individual phonons may travel faster within the one or more nanoholes 410, increasing the relative thermal conductivity. In some embodiments, a plug formed by metal layer 430 within the one or more nanoholes 410 may alter the relative thermal conductivity, with differing materials providing different relative changes to the thermal conductivity, allowing the heat to be focused within the substrate. In some embodiments, a plug formed by metal layer 430 may be referred to as a metal plug.

FIG. 4F depicts at S560 in FIG. 5 a polishing step after forming the metal layer 430 to remove excessive material from one or more of the liner layer 420, the barrier layer 425, the metal layer 430, and the nanostructure substrate 202. In some embodiments, the polishing step may be as planarization process, such as grinding or CMP. In some embodiments, the polishing step may remove any portion of one or more of the liner layer 420, the barrier layer 425, and the metal layer 430 above the surface of the nanostructure substrate 202, while in other embodiments, a portion of one or more of the liner layer 420, the barrier layer 425, and the metal layer 430 may remain. In some embodiments, a portion of the nanostructure substrate 202 may be removed during the polishing step, and may be followed by additional polishing techniques to provide a desired surface roughness.

In some embodiments, after the polishing step at S560, the nanostructure substrate 202 may be subject to one or more additional treatment steps, such as those used in forming a TSV, and may include one or more of a back side polish, the formation of one or more recesses, forming a passivation layer, and a CMP of the passivation layer.

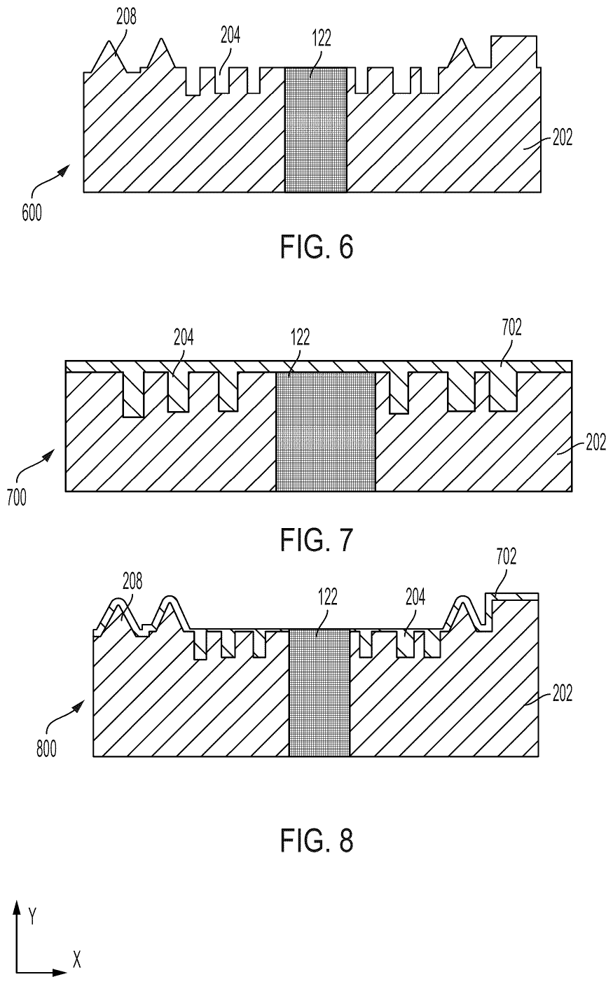

FIG. 6 depicts an exemplary embodiment of a second cooling nanostructure 600 including the wiring layers 122. The exemplary embodiment of the second cooling nanostructure 600 in FIG. 6 differs from the cooling nanostructure 300 of FIGS. 3A and 3B by including multiple types of the one or more nanoelements 210, including the one or more nanoholes 204, the one or more plateaus 206, and the one or more nanopillars 208, such as previously discussed with respect to the fourth configuration 207 of FIG. 2D. In some embodiments, the combination of the one or more nanoholes 204 and the one or more nanopillars 208 may provide a synergistic effect, as the one or more nanoholes 204 may concentrate heat transfer and allow the heat to be directed along a specific path, creating a thermal conductive pathway, while the one or more nanopillars 208 may be used to increase the heat transfer and thermal emissions of the nanostructure substrate 202 as a whole.

FIG. 7 depicts an exemplary embodiment of a third cooling nanostructure 700 including the wiring layers 122. The exemplary embodiment of the third cooling nanostructure 700 of FIG. 7 differs from the cooling nanostructure 300 of FIGS. 3A and 3B by including a metallic layer 702. In some embodiments, the metallic layer 702 may be formed as discussed with the metal layer 430 of FIGS. 4A-4F. In some embodiments, the metallic layer 702 may form a series of metal plugs within the one or more nanoholes 204, may form a surface coating of metal over the nanostructure substrate 202, or a combination thereof. In some embodiments, the metal may be aluminum, while in other embodiments, additional metals such as titanium or tungsten may be used alone or in combination with any suitable metal. In some embodiments, the metal layer 702 over the surface of the nanostructure substrate 202 may form a thermal conductive pathway having both a high emissivity and a high thermal conduction. In some embodiments, the metal layer 702 forming metallic plugs within the one or more nanoholes 204 may form a thermal lens concentrating and directing heat away from the wiring layer 122. In some embodiments, the combination of the metal layer 702 along a surface of the nanostructure substrate 202 and the formation of metallic plugs within the one or more nanoholes 204 may provide both greater thermal conductivity along the substrate as well as a directionality of the heat away from the wiring layer 122.

FIG. 8 depicts an exemplary embodiment of a fourth cooling nanostructure 800 including the wiring layers 122. The exemplary embodiment of the fourth cooling nanostructure 800 of FIG. 8 differs from the second cooling nanostructure 600 of FIG. 6 and the third cooling nanostructure 700 of FIG. 7 by including the metal layer 702 in combination with the one or more nanoelements 210, including the one or more nanoholes 204, the one or more plateaus 206, and the one or more nanopillars 208. In some embodiments, the combination of the metal layer 702 along with the one or more nanoelements 210 may provide an increased cooling effect than any of the individual components.

In some embodiments, a flat silicon substrate such as in the first configuration 201 may have a cooling ramp rate from 70° C. to 45° C. of about 0.62° C./S. In some embodiments, a silicon substrate using the one or more nanopillars 208 such as in the third configuration 205 may have a cooling ramp rate from 70° C. to 45° C. of about 1.68, an improvement of about 2.72-fold over flat silicon. In some embodiments, depositing a layer of aluminum on flat silicon may have a cooling ramp rate from 70° C. to 45° C. of about 2.09, an improvement of about 3.38-fold over flat silicon. In some embodiments, depositing a silicon substrate using the one or more nanoholes 204 when filled with aluminum, such as in the third cooling nanostructure 700 may have a cooling ramp rate from 70° C. to 45° C. of about 2.34, an improvement of about 3.78-fold over flat silicon. In some embodiments, depositing a layer of aluminum on a silicon substrate using the one or more nanopillars 208 such as in the third configuration 205, may have a cooling ramp rate from 70° C. to 45° C. of about 2.41, an improvement of about 3.91-fold over flat silicon In some embodiments, forming a nanostructure having the one or more nanoholes 204 plugged with aluminum on a substrate using the one or more nanopillars 208 such as in the fourth cooling nanostructure 800, may have a cooling ramp rate from 70° C. to 45° C. of about 2.54, an improvement of about 4.11-fold over flat silicon.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A device comprising:
a substrate; and
a computational device mounted on the substrate;
wherein a first surface of the substrate has one or more nanoelements formed within, the one or more nanoelements have a diameter of 100 nm to 5,000 nm.

2. The device of claim 1, further comprising a heat dissipator mounted on the substrate,
wherein the heat dissipator comprises at least one nanostructure;
wherein the one or more nanoelements form a thermal conductive pathway between the computational device and the heat dissipator.

3. The device of claim 1, wherein
the substrate is a silicon substrate, and
the nanoelements extend to a depth of 10 to 15 microns within the silicon substrate.

4. The device of claim 1, wherein a through-via extends between the first surface of the substrate and a second surface of the substrate opposite the first surface;
wherein the one or more nanoelements form a ring around the through-via, wherein the ring has a diameter in the range of 10 to 50 microns.

5. The device of claim 1, wherein the first surface of the substrate includes at least one nanoelements with a size in the range of 100 nm to 5,000 nm.

6. The device of claim 1, wherein the one or more nanoelements comprise a material different than that of the substrate.

7. The device of claim 1, wherein the one or more nanoelements comprise one or more nanoholes, and wherein the one or more nanoholes are filled with a metal plug.

8. A system comprising:
a substrate having a first surface; and
a computational device mounted on the substrate,
wherein the first surface of the substrate includes at least one nanoelement with a diameter in the range of 100 nm to 5,000 nm, the at least one nanoelement formed on the first surface.

9. The system of claim 8, wherein
the substrate is a silicon substrate, and
the at least one nanoelement comprises silicon.

10. The system of claim 8, wherein the at least one nanoelement comprises one or more nanoelements forming a randomly oriented patterned nanostructure.

11. The system of claim 8, wherein the at least one nanoelement comprises at least a first nanoelement having a first size and a first shape and a second nanoelement having a second size and a second shape, wherein the first shape differs from the second shape and the second size differs from the first size.

12. The system of claim 8, wherein a metal layer coats a surface of the at least one nanoelement to form a thermal conductive pathway.

13. The system of claim 8, wherein the first surface of the substrate further comprises one or more nanoholes having a diameter of 100 nm to 5,000 nm, and
wherein a metal layer coats a surface of the at least one nanoelement and plugs the one or more nanoholes.

14. The system of claim 8, further comprising:
a through-via extending between the first surface of the substrate and a second surface of the substrate opposite the first surface; and
a heat dissipator mounted on the first surface of the substrate,
wherein the heat dissipator comprises at least a third nanoelement,
wherein the at least one nanoelement forms a nanostructure on the first surface of the substrate, and
wherein one or more nanoholes and the nanostructure form a thermal conductive path from the through-via to the heat dissipator.

15. The system of claim 8, wherein the at least one nanoelement forms a nanostructured surface over the first surface of the substrate, and wherein the surface area of the nanostructured surface is at least 10 times the surface area of the first surface.

16. A method comprising:
forming a through-via on a substrate;
forming one or more nanoelements on a first surface of the substrate around the through-via on the substrate; and
forming a metal plug within the through-via.

17. The method of claim 16, wherein forming the through-via on a substrate comprises a wet-etch process; and
wherein forming the one or more nanoelements around the through-via on the substrate comprises a dry-etch process.

18. The method of claim 16, wherein forming the one or more nanoelements around the through-via on the substrate comprises forming at least a first set of nanoelements in a ring around the through-via, and forming at least a second set of nanoelements in a ring around the first set of nanoelements.

19. The method of claim 18, further comprise forming a nanostructure including one or more nanoelements on the first surface of the substrate; and
forming a metal layer over the nanostructure;
wherein forming the metal layer over the nanostructure forms a plug in one or more nanoholes.

20. The method of claim 16, further comprising mounting a heat dissipator on the first surface of the substrate;
wherein the heat dissipator comprises at least one nanoelement; and
wherein the one or more nanoelements form a thermal conductive path between the through-via and the heat dissipator.
